(19) United States
(12) Patent Application Publication
(10) Pub. No.: US 2026/0190232 A1
(43) Pub. Date: Jul. 2, 2026

(54) MOLDING COMPOUND APPLICATION IN PRINTED CIRCUIT BOARD BY THREE DIMENSIONAL (3D) STACKING

(71) Applicant: GOOGLE LLC, Mountain View, CA (US)

(72) Inventors: Chan-Wei CHIU, New Taipei City (TW); Ching-Chun TSAI, New Taipei City (TW); Hsin-Hao LEE, New Taipei City (TW)

(73) Assignee: GOOGLE LLC, Mountain View, CA (US)

(21) Appl. No.: 19/127,195

(22) PCT Filed: Dec. 16, 2022
(86) PCT No.: PCT/US2022/053219

§ 371 Date: May 5, 2025

(51) Int. Cl. H05K 1/14; H05K 1/02; H05K 1/181; H05K 3/28; H05K 3/36

(52) U.S. Cl. CPC H05K 1/144; H05K 1/0216; H05K 1/181; H05K 3/284; H05K 3/368; H05K 2201/042; H05K 2201/09036; H05K 2201/10371; H05K 2203/1316

(57) ABSTRACT

Aspects of the disclosure provide two packaging structures each including a first printed circuit board (PCB) having a first top surface and a first bottom surface and a second PCB having a second top surface. In each packaging structure, a first electronic component and a first molding compound layer are disposed on the first top surface of the first PCB, and the first molding compound layer covers the first electronic component. In the first packaging structure, the second PCB is stacked below the first PCB, one of the first PCB and the second PCB has a cavity facing the other of the first PCB and the second PCB, and a second electronic component is disposed inside the cavity. In the second packaging structure, the second PCB is stacked below the first PCB through an interposer frame PCB, and the second electronic component is disposed inside the interposer frame PCB.

### TECHNICAL FIELD

The present disclosure relates to packaging of electronic devices, and specifically relates to molding compound application in printed circuit board.

### BACKGROUND

Three-dimensional (3D) packaging technologies are commonly used in modern electronic products such as smartphone and tablet. In a 3D package, printed circuit boards (PCBs) can be stacked up and electronic devices can be embedded between the PCBs. Further, shielding such as metal shield can be used in the package to prevent electromagnetic interference (EMI).

### SUMMARY

Aspects of the disclosure provide a packaging structure including a first printed circuit board (PCB) having a first top surface and a first bottom surface. A first electronic component and a first molding compound layer are disposed on the first top surface of the first PCB, and the first molding compound layer covers the first electronic component. The packaging structure further includes a second PCB having a second top surface. The second PCB is stacked below the first PCB such that the second top surface of the second PCB faces the first bottom surface of the first PCB. One of the first PCB and the second PCB has a cavity facing the other of the first PCB and the second PCB. A second electronic component is disposed inside the cavity.

In an embodiment, a first region of the first molding compound layer is higher than a second region of the first molding layer.

In an embodiment, the first molding compound layer includes a metal partition separating the first molding compound layer into a plurality of regions.

In an embodiment, the packaging structure further includes a shielding fence surrounding the first molding compound layer.

In an embodiment, the packaging structure further includes a liquid metal coating layer covering the first molding layer and the shielding fence.

In an embodiment, the packaging structure further includes a third electronic component on a second bottom surface of the second PCB.

In an embodiment, the packaging structure further includes a second molding compound layer on the second bottom surface of the second PCB and covering the third electronic component.

Aspects of the disclosure further provide a packaging structure including a first printed circuit board (PCB) having a first top surface and a first bottom surface. A first electronic component and a first molding compound layer are disposed on the first top surface of the first PCB, and the first molding compound layer covers the first electronic component. The packaging structure further includes an interposer frame PCB below the first bottom surface of the first PCB and a second PCB having a second top surface. The second PCB is stacked below the first PCB through the interposer frame PCB such that the second top surface of the second PCB faces the first bottom surface of the first PCB. A second electronic component is disposed inside the interposer frame PCB.

In an embodiment, a first region of the first molding compound layer is higher than a second region of the first molding layer.

In an embodiment, the first molding compound layer includes a metal partition separating the first molding compound layer into a plurality of regions.

In an embodiment, the packaging structure further includes a shielding fence surrounding the first molding compound layer.

In an embodiment, the packaging structure further includes a liquid metal coating layer covering the first molding layer and the shielding fence.

In an embodiment, the second top surface of the second PCB faces the first bottom surface of the first PCB.

In an embodiment, the packaging structure further includes a third electronic component on a second bottom surface of the second PCB.

In an embodiment, the packaging structure further includes a second molding compound layer on the second bottom surface of the second PCB and covering the third electronic component.

Aspects of the disclosure further provide a method of manufacturing a packaging structure including a first printed circuit board (PCB) and a second PCB. The first PCB has a first top surface and a first bottom surface that is opposite to the first top surface. The second PCB has a second top surface and a second bottom surface that is opposite to the second top surface. Under the method, a first electronic component is disposed on the first top surface of the first PCB, a first molding compound layer is formed on the first top surface of the first PCB to cover the first electronic component, and the first PCB is stacked above the second PCB such that the second top surface of the second PCB faces the first bottom surface of the first PCB.

In an embodiment, one of the first PCB and the second PCB has a cavity, and a second electronic component is disposed into the cavity.

In an embodiment, the packaging structure includes an interposer frame PCB, and the first PCB is stacked above the second PCB through the interposer frame PCB.

In an embodiment, a third electronic component is disposed on the second bottom surface of the second PCB, and a second molding compound layer is formed on the second bottom surface of the second PCB to cover the third electronic component.

In an embodiment, a shielding fence is formed to surround the first molding compound layer, and a liquid metal coating layer is formed to cover the first molding compound layer and the shielding fence.

Aspects of the disclosure further provide a non-transitory computer-readable medium storing a program implementing the above method.

### BRIEF DESCRIPTION OF THE DRAWINGS

Various embodiments of this disclosure that are proposed as examples will be described in detail with reference to the following figures, wherein like numerals reference like elements, and wherein:

FIG. 1 shows a stack-up packaging structure according to an embodiment of the disclosure;

FIGS. 2A-2H show various packaging structures each including a cavity board according to embodiments of the disclosure;

FIGS. 3A-3C show various packaging structures each including an interposer frame board according to embodiments of the disclosure;

FIG. 4 shows a flowchart outlining a process of manufacturing the packaging structures according to embodiments of the disclosure; and

FIG. 5 is a schematic of a hardware configuration of a device for manufacturing the packaging structures according to embodiments of the present disclosure.

### DETAILED DESCRIPTION OF EMBODIMENTS

An electronic system can be packaged by using system-in-package (SiP) technology, in which multiple electronic components, such as surface-mount technology (SMT) components, integrated circuit (IC) chips, and IC dies, can be enclosed in a single package, by using package-on-package for example. Therefore, multiple substrates can be included in the SiP. In some cases, a size of the electronic system is constrained, such as the electronic system in a consumer product (e.g., in a smartphone or smart watch). Accordingly, the multiple substrates in the SiP can be vertically stacked up to form a stack-up packaging structure.

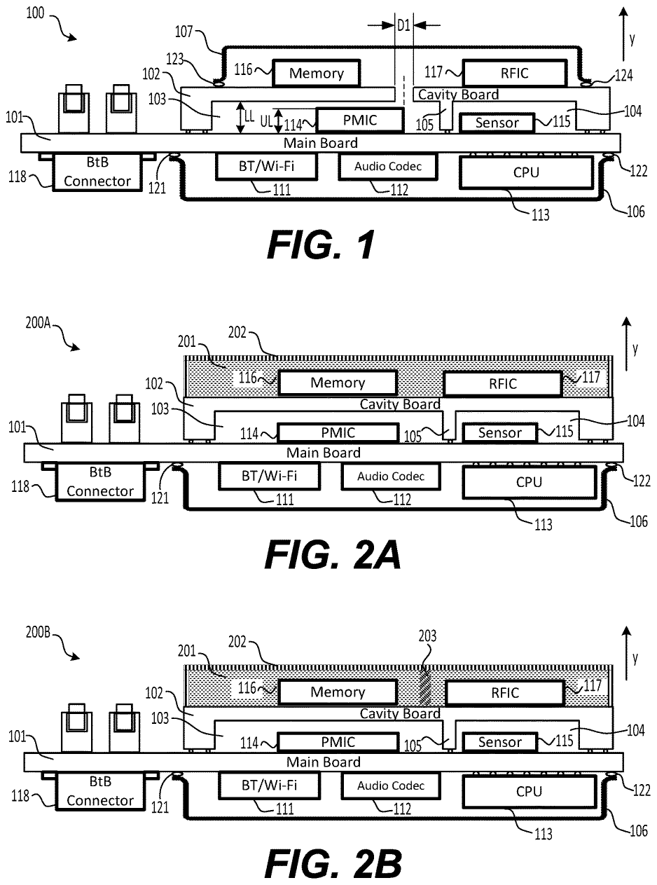

FIG. 1 shows a stack-up packaging structure 100 according to an embodiment of the disclosure. The packaging structure 100 includes a main board 101 and a cavity board 102. Both boards can be printed circuit boards (PCB), of which the material can be any suitable material such as glass (e.g., FR4), ceramic (e.g., RF-35), or metal (e.g., copper, aluminum, or iron). The cavity board 102 is stacked above the main board 101 along its height direction (y-direction), and is electrically connected to the main board 101. The cavity board 102 includes two cavities 103 and 104 which are separated by a partition 105 of the cavity board 102. It is noted that the two cavities shown in FIG. 1 are just for illustration, and a number of cavities included in the cavity board 102 is not limited. In an example, there is no partition in the cavity board 102. In an example, there is only one partition in the cavity board 102. In an example, there are more than two partitions in the cavity board 102.

According to aspects of the disclosure, one or more electronic devices, such as surface-mount technology (SMT) components, integrated circuit (IC) chips, and IC dies, can be mounted and packaged into the packaging structure 100. For example, as shown in FIG. 1, a Bluetooth (BT) and Wi-Fi module 111, an audio codec chip 112, and a central processing unit (CPU) chip 113 are mounted on a bottom side of the main board 101, and are covered by a shield 106. The shield 106 is mounted on the bottom side of the main board 101 through solder paste 121 and 122, and can be a metal shield such as copper foil. A power management IC (PMIC) chip 114 is mounted on a top side of the main board 101 and inside the cavity 103 of the cavity board 102. A sensor 115 is mounted on the top side of the main board 101 and inside the cavity 104 of the cavity board 102. A memory device 116 and a radio frequency IC (RFIC) chip 117 are mounted on a top side of the cavity board 102, and are covered by a shield 107. The shield 107 is mounted on the top side of the cavity board 102 through solder paste 123 and 124, and can be a metal shield such as copper foil. In addition, the packaging structure 100 can include a board-to-board connector 118.

According to embodiments of the disclosure, the cavity board 102 can include one or more holes (or gaps) such as the hole D1 shown in FIG. 1. If underfill is not required for a device inside the cavity such as the PMIC chip 114 or the sensor 115, the hole D1 can be used for air escaping, and a diameter of the hole D1 can be set as 0.5 mm for example. If the underfill is required for a device inside the cavity, the hole DI can be used for injecting the underfill into the cavity. Accordingly, the hole D1 should be on top of the device, and a centralized line of the hole D1 should be aligned with an edge of the device. In addition, the diameter of the hole D1 can be set as 1.5 mm hole for example.

In an embodiment, a gap between an upper limit (UL) of a component height and a lower limit (LL) of a cavity depth is greater than a threshold. For example, the gap between the component UL and cavity depth LL should be at least 0.1 mm, the component UL is less than 1.0 mm, and the cavity depth LL is greater than 1.1 mm.

As described above, the main board 101 and the cavity board 102 can be stacked up together using a PCB stack-up process. During the PCB stack-up process, when the shield 106 (or 107) is a big shield, the solder paste 121-122 (or 123-124) may not be solid at the same time. A large solid time difference can cause a serious impact to the quality of the PCB. For example, the large solid time difference can cause the PCB warpage and further lead to a serious process yield loss.

To reduce the impact to the quality of the PCB, a molding compound can be used to replace the shield 106 (and/or 107) in the packaging structure 100. The molding compound is solid during the PCB stack-up process and can provide good rigidity to reduce the risk of the PCB warpage.

Other benefits of using the molding compound instead of the metaling shield to cover the electronic components include, but are not limited to, minimizing the PCB size, improving the heating dissipation efficiency, reducing the thickness of the packaging structure, and improving the electromagnetic interference (EMI) shielding efficiency.

For example, when the molding compound is used to cover the electronic components, the solder crack risk of a small chip such as a small pitch ball grid array (BGA) packaged chip can be reduced during the drop or tumble reliability test. Also, the potential electrical short among the components, which is a long time reliability risk, can be avoided by using the molding compound, so the layout spacing between the components can be reduced.

In addition, the increasing heat is a major risk of the packaging structure. The solid molding compound can have better heating dissipation ability compared to the metal shield. Therefore, by choosing a high conductivity molding material, the heating dissipation efficiency can be improved. For example, the molding material may be an epoxy based resin or other suitable commercially available material.

The thickness of the packaging structure can be reduced by using the molding compound. For example, the molding compound can be grinded to a target height that is less than a height of the shield. Further, the molding compound can have an irregular shape to reduce the height of a partial region of the molding compound.

The EMI shielding efficiency of the packaging structure can be improved by using the molding compound. For example, by applying a liquid metal coating on the molding compound, the EMI shielding (or masking) efficiency of the packaging structure can be higher compared to that of the packaging structure using the metal shield.

This disclosure presents embodiments of stack-up packaging structures with a molding compound.

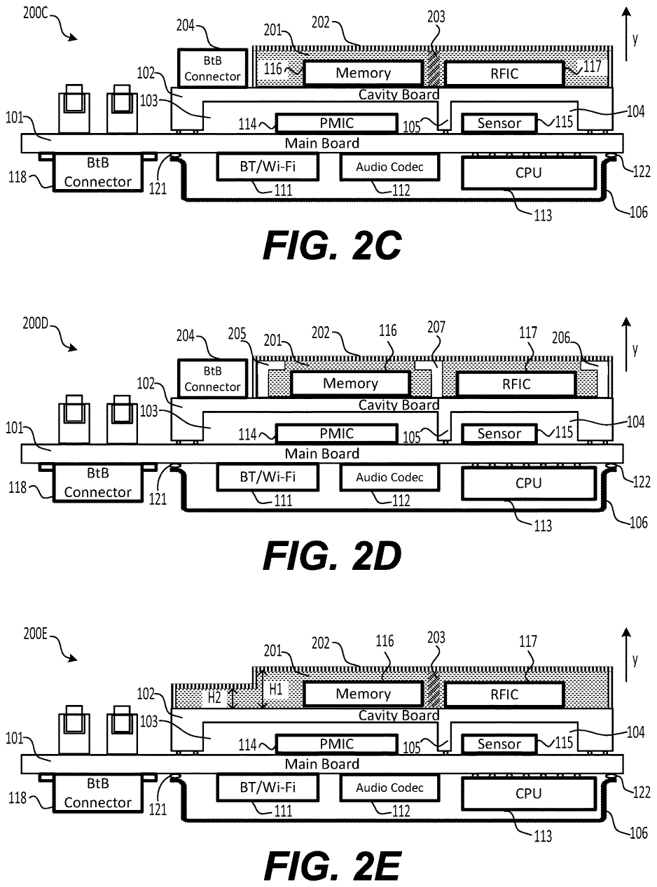

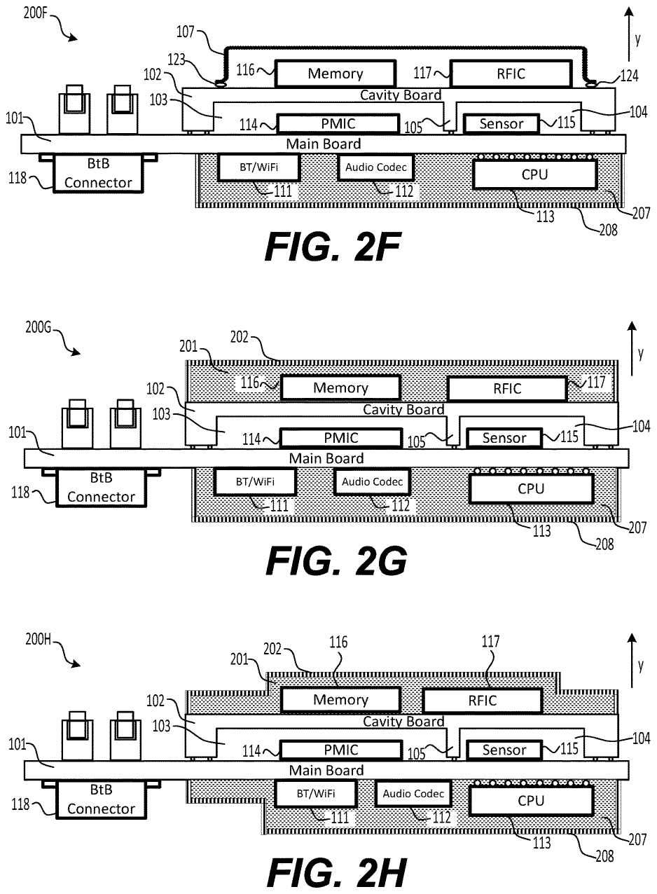

FIGS. 2A-2H show various packaging structures 200A-200H with the molding compound according to embodiments of the disclosure.

Specifically, the packaging structure 200A in FIG. 2A includes a molding compound 201 to replace the metal shield 107 of the packaging structure 100 in FIG. 1. The molding compound 201 is disposed on top surface of the cavity board 102 and covers all electronic components that are placed on the top surface of the cavity board 102, such as the memory device 116 and the RFIC chip 117. Accordingly, this molding compound 201 can be referred to as a full molding compound. The packaging structure 200A also includes a liquid metal coating 202 that is disposed on a top surface of the molding compound 201 and surrounds the molding compound 201. That is, the liquid metal coating 202 fully covers the molding compound 201, so that the EMI shielding efficiency of the packaging structure 200A can be improved.

Compared to the packaging structure 200A, the packaging structure 200B in FIG. 2B includes a metal partition 203 inside the molding compound 201. The metal partition 203 can provide an EMI shield between the memory device 116 and the RFIC chip 117 so that the EMI from the RFIC chip 117 to the memory device 116 can be reduced. It is noted that a number of metal partitions is not limited in this disclosure. For example, the packaging structure 200B can have zero or more than one metal partition.

The packaging structure 200C shown in FIG. 2C includes a board-to-board connector 204 on the top surface of the cavity board 102. The board-to-board connector 204 is not covered by the molding compound 201. In this case, the molding compound 201 can be referred to as a partial molding compound.

The packaging structure 200D shown in FIG. 2D includes shielding frames (or shielding fences) 205 and 206 and shielding partition 207. The shielding frames 205 and 206 surround the molding compound 201 and are covered by the liquid metal coating 202. The shielding partition 207 can provide an EMI shield between the memory device 116 and the RFIC chip 117 in order to reduce the EMI from the RFIC chip 117 to the memory device 116. It is noted that a number of shielding frames and shielding partitions is not limited in this disclosure.

The packaging structure 200E shown in FIG. 2E includes an irregular shape of molding compound 201, in which a region with a height of H1 is higher than another region with a height of H2. The irregular type of molding compound 201 can reduce the thickness of the packaging structure 200E.

According to aspects of the disclosure, any one or both of the metal shields 106 and 107 in the packaging structure 100 in FIG. 1 can be replaced with the molding compound.

FIG. 2F shows the packaging structure 200F in which a molding compound 207 is disposed on the bottom surface of the main board 101 and covers the Bluetooth (BT) and Wi-Fi module 111, the audio codec chip 112, and the CPU chip 113. In addition, a liquid metal coating 208 fully covers the molding compound 207.

FIG. 2G shows the packaging structure 200G in which both molding compound 201 and 207 are disposed on the top surface of the cavity board 102 and the bottom surface of the main board 101, respectively. In addition, in an embodiment, the liquid metal coatings 202 and 208 fully cover the molding compound 201 and 207, respectively.

FIG. 2H shows the packaging structure 200H in which both molding compounds 201 and 207 have the irregular shape. That is, a region of the molding compound 201 (or 207) is higher than another region of the molding compound 201 (or 207), so that the height of the packaging structure 200H can be reduced.

It is noted that the packaging structures 200A-200H are just for illustration and various variations and/or combinations of these packaging structures are not limited in this disclosure. For example, any one or both of the molding compounds in the packaging structure 200G (or 200H) can include the metal partition 203 and/or shielding frames 205-206. Any one of both of the molding compounds in the packaging structure 200G (or 200H) can be full molding compound, partial molding compound, or irregular shape of molding compound.

According to aspects of the disclosure, an upper board can be stacked above the main board through an interposer frame board, and the molding compound can be disposed on a top surface of the upper board to cover one or more electronic components on the top surface of the upper board.

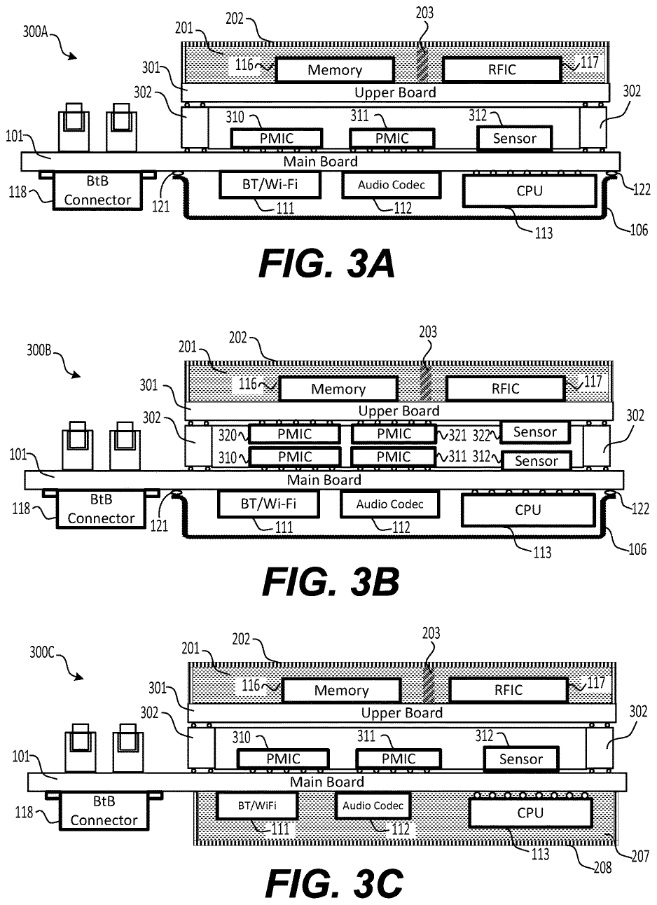

FIG. 3A shows a packaging structure 300A including an upper board 301 that is stacked above the main board 101 through an interposer frame board 302. The upper board 301 can be electrically connected to the main board 101 through the interposer frame board 302. The memory device 116 and the RFIC chip 117 are soldered on the top surface of the upper board 301. The molding compound 201 is also disposed on the top surface of the upper board 301 and fully covers the memory device 116 and the RFIC chip 117. The metal partition 203 separates the molding compound 201 into multiple regions and can provide an EMI shield between the memory device 116 and the RFIC chip 117.

According to aspects of the disclosure, one or more electronic components can be disposed inside the interposer frame board 302. For example, as shown in FIG. 3A, two PMIC chips 310 and 311 and a sensor device 312 are soldered on the top surface of the main board 101 and inside the interposer frame board 302. In an example, as shown in FIG. 3B, besides the two PMIC chips 310 and 311 and the sensor device 312, two other PMIC chips 320 and 321 and another sensor device 322 are soldered on the bottom surface of the upper board 301 and inside the interposer frame board 302.

In an embodiment, the molding compound can be disposed on the bottom surface of the main board 101 to cover the electronic components on the bottom surface of the main board 101. The molding compound can also be disposed on both the top surface of the upper board 301 and the bottom surface of the main board 101, as shown in FIG. 3C.

It is noted that the packaging structures 300A-300C are just for illustration and various variations and/or combinations of the these packaging structures are not limited in this disclosure. For example, any one or both of the molding compounds in the packaging structure 300C can be partial molding compound, full molding compound, or irregular shape of molding compound. Any one or both of the molding compounds in the packaging structure 300C can include the metal partition 203 and/or shielding frames 205-206.

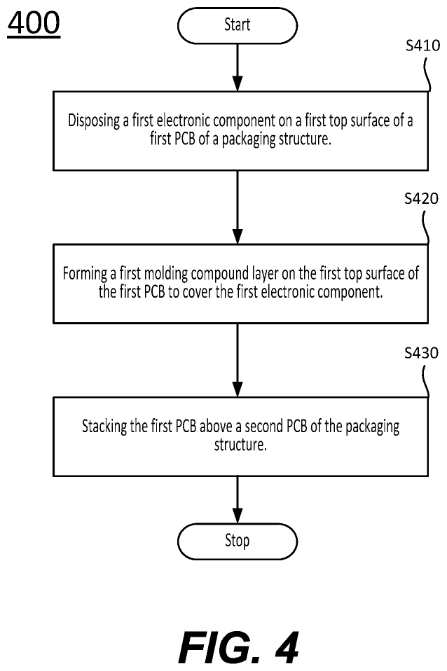

The embodiments described above can be implemented using a process (400) shown in FIG. 4. The process (400) can be executed by processing circuitry of a device for manufacturing a packaging structure. The process (400) can be implemented in software instructions, and, when the processing circuitry executes the software instructions, the processing circuitry performs the process (400).

The process (400) may generally start at step (S410), where a first electronic component is disposed on a first top surface of a first PCB of the packaging structure. Then, the process (400) proceeds to step (S420).

At step (S420), a first molding compound layer is formed on the first top surface of the first PCB to cover the first electronic component. Then, the process (400) proceeds to step (S430).

At step (S430), the first PCB is stacked above a second PCB of the packaging structure, such that a second top surface of the second PCB faces a first bottom surface of the first PCB.

In an embodiment, one of the firs PCB and the second PCB has a cavity, and a second electronic component is disposed into the cavity.

In an embodiment, the packaging structure includes an interposer frame PCB, and the first PCB is stacked above the second PCB through the interposer frame PCB.

In an embodiment, a third electronic component is disposed on a bottom surface of the second PCB, and a second molding compound layer is formed on the second bottom surface of the second PCB to cover the third electronic component.

In an embodiment, a shielding fence is formed to surround the first molding compound layer, and a liquid metal coating layer is formed to cover the first molding compound layer and the shielding fence.

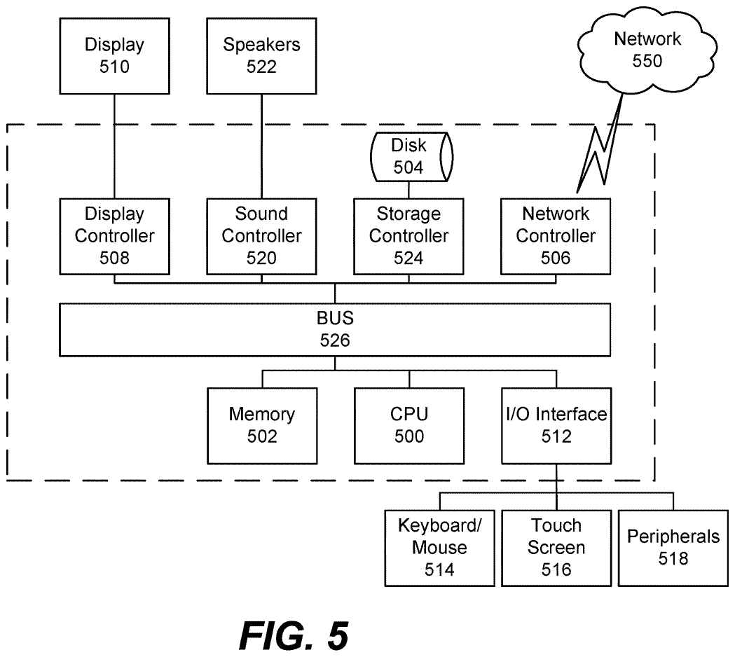

FIG. 5 shows a hardware description of a device for manufacturing the packaging structures according to embodiments of the disclosure. In FIG. 5, the device includes a CPU 500 which performs the processes described above/below, the CPU being a part of the processing circuitry. The process data and instructions may be stored in memory 502. These processes and instructions may also be stored on a storage medium disk 504 such as a hard drive (HDD) or portable storage medium or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the device communicates, such as a server or computer.

Further, the claimed advancements may be provided as a utility application, background daemon, or component of an operating system, or combination thereof, executing in conjunction with CPU 500 and an operating system such as Microsoft Windows, UNIX, Solaris, LINUX, Apple MAC-OS and other systems known to those skilled in the art.

The hardware elements in order to achieve the device may be realized by various circuitry elements, known to those skilled in the art. For example, CPU 500 may be a Xenon or Core processor from Intel of America or an Opteron processor from AMD of America, or may be other processor types that would be recognized by one of ordinary skill in the art. Alternatively, the CPU 500 may be implemented on an FPGA, ASIC, PLD or using discrete logic circuits, as one of ordinary skill in the art would recognize. Further, CPU 500 may be implemented as multiple processors cooperatively working in parallel to perform the instructions of the processes described above.

The apparatus in FIG. 5 also includes a network controller 506, such as an Intel Ethernet PRO network interface card from Intel Corporation of America, for interfacing with network 550. As can be appreciated, the network 550 can be a public network, such as the Internet, or a private network such as an LAN or WAN network, or any combination thereof and can also include PSTN or ISDN sub-networks. The network 550 can also be wired, such as an Ethernet network, or can be wireless such as a cellular network including EDGE, 3G, 4G and 5G wireless cellular systems. The wireless network can also be Wi-Fi, Bluetooth, or any other wireless form of communication that is known.

The device further includes a display controller 508, such as a NVIDIA Geforce GTX or Quadro graphics adaptor from NVIDIA Corporation of America for interfacing with display 510, such as an LCD monitor. A general purpose I/O interface 512 interfaces with a keyboard and/or mouse 514 as well as a touch screen panel 516 on or separate from display 510. General purpose I/O interface also connects to a variety of peripherals 518 including printers and scanners.

A sound controller 520 is also provided in the device to interface with speakers/microphone 522 thereby providing sounds and/or music.

The general-purpose storage controller 524 connects the storage medium disk 504 with communication bus 526, which may be an ISA, EISA, VESA, PCI, or similar, for interconnecting the components of the device. A description of the general features and functionality of the display 510, keyboard and/or mouse 514, as well as the display controller 608, storage controller 524, network controller 506, sound controller 520, and general purpose I/O interface 512 is omitted herein for brevity as these features are known.

Obviously, numerous modifications and variations are possible in light of the above teachings. It is therefore to be understood that within the scope of the appended claims, the embodiments may be practiced otherwise than as specifically described herein.

Aspects of the disclosure provide a packaging structure including a first printed circuit board (PCB) having a first top surface and a first bottom surface. A first electronic component and a first molding compound layer are disposed on the first top surface of the first PCB, and the first molding compound layer covers the first electronic component. The packaging structure further includes a second PCB having a second top surface. The second PCB is stacked below the first PCB such that the second top surface of the second PCB faces the first bottom surface of the first PCB. One of the first PCB and the second PCB has a cavity facing the other of the first PCB and the second PCB. A second electronic component is disposed inside the cavity.

In an embodiment, a first region of the first molding compound layer is higher than a second region of the first molding layer.

In an embodiment, the first molding compound layer includes a metal partition separating the first molding compound layer into a plurality of regions.

In an embodiment, the packaging structure further includes a shielding fence surrounding the first molding compound layer.

In an embodiment, the packaging structure further includes a liquid metal coating layer covering the first molding layer and the shielding fence.

In an embodiment, the packaging structure further includes a third electronic component on a second bottom surface of the second PCB.

In an embodiment, the packaging structure further includes a second molding compound layer on the second bottom surface of the second PCB and covering the third electronic component.

Aspects of the disclosure further provide a packaging structure including a first printed circuit board (PCB) having a first top surface and a first bottom surface. A first electronic component and a first molding compound layer are disposed on the first top surface of the first PCB, and the first molding compound layer covers the first electronic component. The packaging structure further includes an interposer frame PCB below the first bottom surface of the first PCB and a second PCB having a second top surface. The second PCB is stacked below the first PCB through the interposer frame PCB such that the second top surface of the second PCB faces the first bottom surface of the first PCB. A second electronic component is disposed inside the interposer frame PCB.

In an embodiment, a first region of the first molding compound layer is higher than a second region of the first molding layer.

In an embodiment, the first molding compound layer includes a metal partition separating the first molding compound layer into a plurality of regions.

In an embodiment, the packaging structure further includes a shielding fence surrounding the first molding compound layer.

In an embodiment, the packaging structure further includes a liquid metal coating layer covering the first molding layer and the shielding fence.

In an embodiment, the second top surface of the second PCB faces the first bottom surface of the first PCB.

In an embodiment, the packaging structure further includes a third electronic component on a second bottom surface of the second PCB.

In an embodiment, the packaging structure further includes a second molding compound layer on the second bottom surface of the second PCB and covering the third electronic component.

Aspects of the disclosure further provide a method of manufacturing a packaging structure including a first printed circuit board (PCB) and a second PCB. The first PCB has a first top surface and a first bottom surface that is opposite to the first top surface. The second PCB has a second top surface and a second bottom surface that is opposite to the second top surface. Under the method, a first electronic component is disposed on the first top surface of the first PCB, a first molding compound layer is formed on the first top surface of the first PCB to cover the first electronic component, and the first PCB is stacked above the second PCB such that the second top surface of the second PCB faces the first bottom surface of the first PCB.

In an embodiment, one of the first PCB and the second PCB has a cavity, and a second electronic component is disposed into the cavity.

In an embodiment, the packaging structure includes an interposer frame PCB, and the first PCB is stacked above the second PCB through the interposer frame PCB.

In an embodiment, a third electronic component is disposed on the second bottom surface of the second PCB, and a second molding compound layer is formed on the second bottom surface of the second PCB to cover the third electronic component.

In an embodiment, a shielding fence is formed to surround the first molding compound layer, and a liquid metal coating layer is formed to cover the first molding compound layer and the shielding fence.

Aspects of the disclosure further provide a non-transitory computer-readable medium storing a program implementing the above method.

While aspects of the present disclosure have been described in conjunction with the specific embodiments thereof that are proposed as examples, alternatives, modifications, and variations to the examples may be made. Accordingly, embodiments as set forth herein are intended to be illustrative and not limiting. There are changes that may be made without departing from the scope of the claims set forth below.

What is claimed is:

1. A packaging structure, comprising:
a first printed circuit board (PCB) having a first top surface and a first bottom surface;
a first electronic component on the first top surface of the first PCB;
a first molding compound layer on the first top surface of the first PCB and covering the first electronic component; and
a second PCB having a second top surface,
wherein the second PCB is stacked below the first PCB such that the second top surface of the second PCB faces the first bottom surface of the first PCB, one of the first PCB and the second PCB has a cavity facing the other of the first PCB and the second PCB, and a second electronic component is disposed inside the cavity.

2. The packaging structure of claim 1, wherein a first region of the first molding compound layer is higher than a second region of the first molding layer.

3. The packaging structure of claim 1, wherein the first molding compound layer includes a metal partition separating the first molding compound layer into a plurality of regions.

4. The packaging structure of claim 1, further comprising:
a shielding fence surrounding the first molding compound layer.

5. The packaging structure of claim 4, further comprising:
a liquid metal coating layer covering the first molding layer and the shielding fence.

6. The packaging structure of claim 1, further comprising:
a third electronic component on a second bottom surface of the second PCB.

7. The packaging structure of claim 6, further comprising:
a second molding compound layer on the second bottom surface of the second PCB and covering the third electronic component.

8. A packaging structure, comprising:
a first printed circuit board (PCB) having a first top surface and a first bottom surface;
a first electronic component on the first top surface of the first PCB;
a first molding compound layer on the first top surface of the first PCB and covering the first electronic component;
an interposer frame PCB below the first bottom surface of the first PCB; and
a second PCB having a second top surface,
wherein the second PCB is stacked below the first PCB through the interposer frame PCB such that the second top surface of the second PCB faces the first bottom surface of the first PCB, and a second electronic component is disposed inside the interposer frame PCB.

9. The packaging structure of claim 8, wherein a first region of the first molding compound layer is higher than a second region of the first molding layer.

10. The packaging structure of claim 8, wherein the first molding compound layer includes a metal partition separating the first molding compound layer into a plurality of regions.

11. The packaging structure of claim 8, further comprising:
a shielding fence surrounding the first molding compound layer.

12. The packaging structure of claim 11, further comprising:
a liquid metal coating layer covering the first molding layer and the shielding fence.

13. The packaging structure of claim 8, wherein the second top surface of the second PCB faces the first bottom surface of the first PCB.

14. The packaging structure of claim 13, further comprising:
a third electronic component on a second bottom surface of the second PCB.

15. The packaging structure of claim 14, further comprising:
a second molding compound layer on the second bottom surface of the second PCB and covering the third electronic component.

16. A method of manufacturing a packaging structure including a first printed circuit board (PCB) and a second PCB, wherein the first PCB has a first top surface and a first bottom surface that is opposite to the first top surface, the second PCB has a second top surface and a second bottom surface that is opposite to the second top surface, the method comprises:
disposing a first electronic component on the first top surface of the first PCB;
forming a first molding compound layer on the first top surface of the first PCB to cover the first electronic component; and
stacking the first PCB above the second PCB such that the second top surface of the second PCB faces the first bottom surface of the first PCB.

17. The method of claim 16, wherein one of the first PCB and the second PCB has a cavity, and the method further comprises:
disposing a second electronic component into the cavity.

18. The method of claim 16, wherein the packaging structure includes an interposer frame PCB, and the method further comprises:
stacking the first PCB above the second PCB through the interposer frame PCB.

19. The method of claim 16, further comprising:
disposing a third electronic component on the second bottom surface of the second PCB; and
forming a second molding compound layer on the second bottom surface of the second PCB to cover the third electronic component.

20. The method of claim 16, further comprising:
forming a shielding fence to surround the first molding compound layer; and
forming a liquid metal coating layer to cover the first molding compound layer and the shielding fence.
